(19) United States
(12) Patent Application Publication
(10) Pub. No.: US 2013/0074697 A1
(43) Pub. Date: Mar. 28, 2013

(54) FILTER FOR ELECTRICAL EQUIPMENT

(71) Applicants: Teri F. Verschoor, Rocklin, CA (US); Glenn C. Simon, Auburn, CA (US); James D. Hensley, Rocklin, CA (US); David G. Rohrer, Roseville, CA (US)

(72) Inventors: Teri F. Verschoor, Rocklin, CA (US); Glenn C. Simon, Auburn, CA (US); James D. Hensley, Rocklin, CA (US); David G. Rohrer, Roseville, CA (US)

(21) Appl. No.: 13/247,146

(22) Filed: Sep. 28, 2011

(51) Int. Cl. H05K 7/20; B01D 29/05

(52) U.S. Cl. 95/273; 361/692; 55/511; 55/486

(57) ABSTRACT

An air filter for electrical equipment includes metallic filter media including a first outer layer, an opposing second outer layer, and at least one inner layer disposed between the first outer layer and the opposing second outer layer, and a frame disposed along a perimeter edge of the filter media configured to retain the filter media.

### BACKGROUND

Dust filtration in networking equipment can be a concern, particularly in new networking environments. Some recent networking equipment deployment practices include decentralization of networking equipment, “outside air cooling” with air side economizers, portable data centers, and even deployment in tents. Many of these recent deployment practices employ networking equipment into dirty environments, which escalates risk of damage due to overheating the networking equipment. Additionally, emerging markets have increased contamination risk due to uncontrolled air quality environments in which the equipment is placed.

Electromagnetic interference (EMI) solutions and high density heat sinks in equipment also add new potential for dust to accumulate in unserviceable areas of networking equipment. Dust fouling impedes cooling solutions, although it may take several years, thus eluding detection in traditional development testing. Increased contamination increases the vulnerability of the equipment and leads to additional maintenance, down time, and costly service in the field.

Existing dust filter technology is not well suited for many networking equipment applications. Most available dust filtration solutions are designed to remove a very high percentage of all particulate matter, including extremely fine particulates. This is despite that most small particulate passes straight through computing equipment with very little effect on cooling efficiency. The primary threat to cooling solutions is from “long fiber” dust, such as cotton or cardboard fibers, for example. Existing filters typically clog rapidly and reduce cooling performance.

### BRIEF DESCRIPTION OF THE DRAWINGS

FIG. 1 is a prospective view of one embodiment of a networking equipment.

FIGS. 2A-2C are views of one embodiment of a filter assembly.

FIGS. 3A-3B are views of one embodiment of a filter assembly.

FIG. 4 is a plan view of one embodiment of a filter.

FIG. 5 is a block diagram of one embodiment of a method.

FIG. 6A is a cross-sectional view of one embodiment of a networking equipment and air flow.

FIG. 6B is a cross-sectional view of one embodiment of a networking equipment and air flow.

FIG. 7A is one embodiment of a networking equipment and thermal flow.

FIG. 7B is one embodiment of a networking equipment and thermal flow.

### DETAILED DESCRIPTION

In the following detailed description, reference is made to the accompanying drawings which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that features of the various embodiments described herein may be combined with each other, unless specifically noted otherwise.

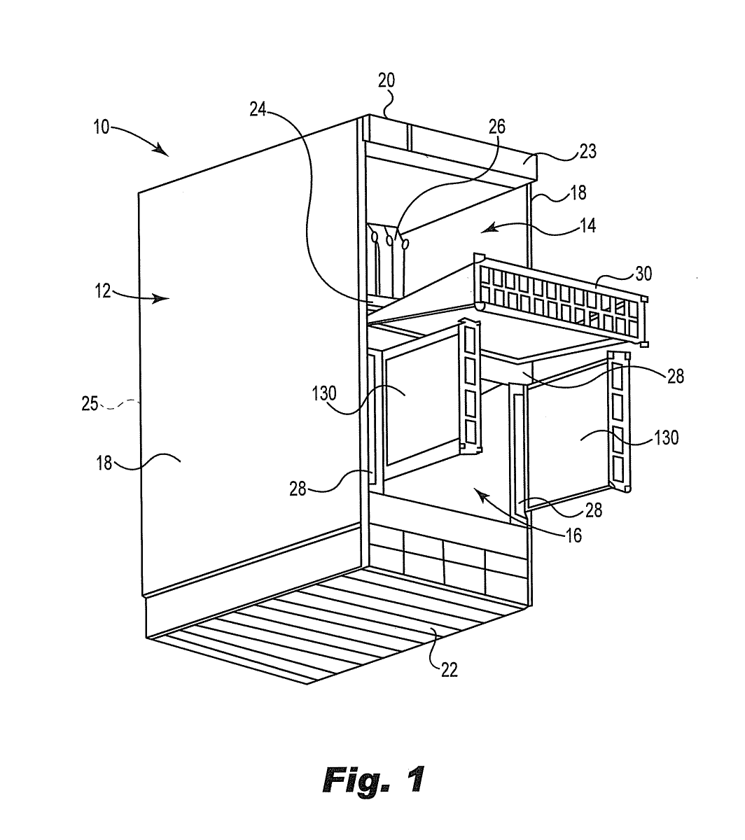

Embodiments provide techniques of filtering air for electrical equipment. The air filtration techniques minimize air flow impedance, smooth air flow, and maximize dust collection. FIG. 1 illustrates one embodiment of a networking equipment 10 including filter assemblies 30 and 130. In example embodiments, electrical equipment 10 is a bladed networking switch or similar data communication device. An enclosure 12 of electrical equipment 10 includes sides 18, a top 20 and a bottom 22. Enclosure 12 of electrical equipment 10 includes at least one chassis. In one embodiment, enclosure 12 defines multiple plane shaped chassis 14 and 16 to hold respective electronic card cages, for example. Top chassis 14 and bottom chassis 16 include electrical component slots 26 which are configured to house pluggable electronic modules such as cards (not shown). In one embodiment, a common boundary divider 24 divides top chassis 14 from bottom chassis 16.

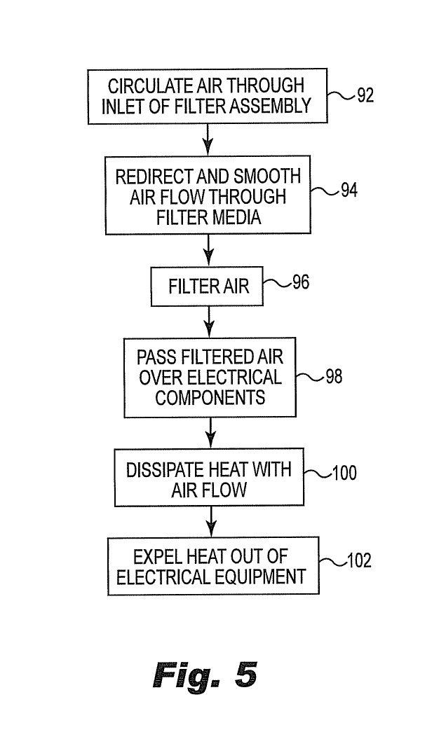

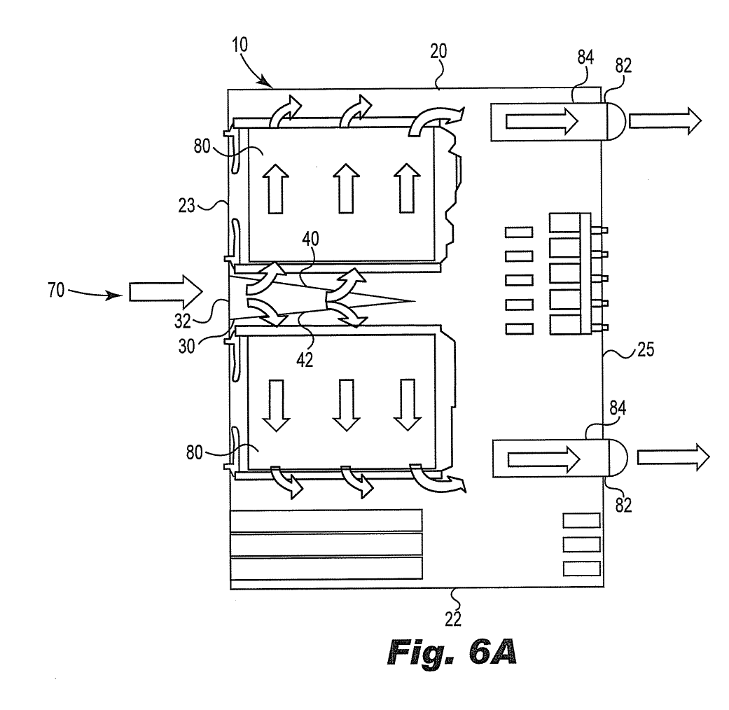

The at least one chassis (e.g. top chassis 14 and bottom chassis 16) is arranged to contain an air stream provided by a cooling subsystem formed by filter assemblies 30 and 130 and optionally at least one fan 84. (see FIGS. 6A, 6B) The airstream flows from an air intake side of electrical equipment 10, through the interior cavity of chassis 14, 16, and to an air exhaust side of electrical equipment 10. In one embodiment, the air intake side is opposite the air exhaust side of electrical equipment 10 with the air intake side arranged on a front 23 of enclosure 12 and the air exhaust side arranged on a back 25 of enclosure 12. The air intake and air exhaust are arranged to draw air into and through chassis 14, 16 in order to remove heat from the operating components within electrical equipment 10.

Filter assemblies 30, 130 are illustrated extended from enclosure 12 in FIG. 1 for clarity. In one embodiment, filter assemblies 30, 130 are insertable through front 23 of enclosure 12 via filter assembly guides 28. Filter assemblies 30, 130 allow ambient air to flow into electrical equipment 10. Additionally, in one embodiment, filter assemblies 30, 130 provide electromagnetic interference shielding (EMI) and radio frequency interference (RFI) containment. In one embodiment, networking equipment 10 includes at least one primary filter assembly 30 positioned within enclosure 12 along a first plane, for example, between top chassis 14 and bottom chassis 16, and at least two secondary filter assemblies 130 positioned along a second and a third plane, for example, along the interior of opposing sides 18 of enclosure 12.

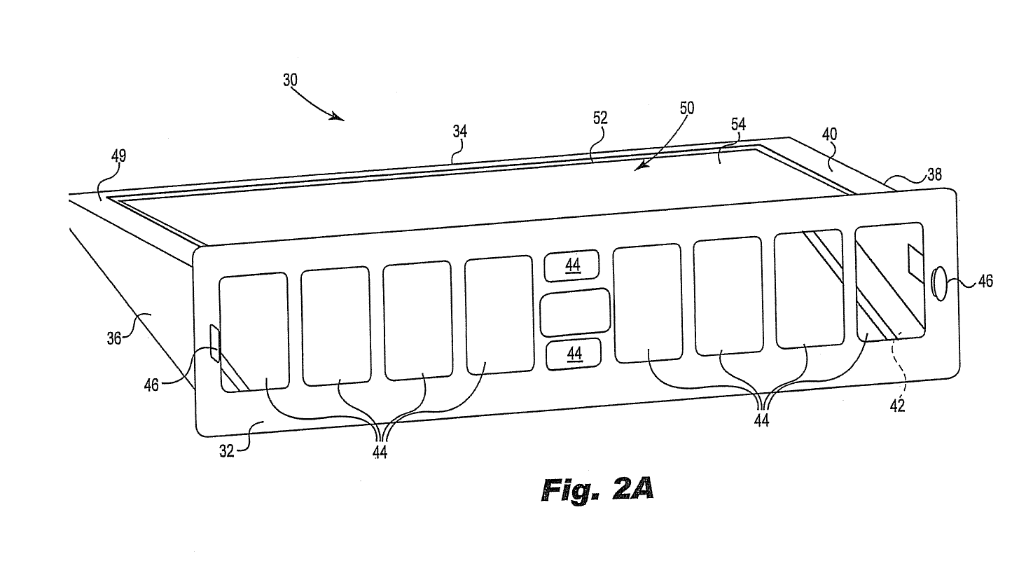

In one embodiment, a mechanism 46 (such as mechanism 46 illustrated in FIGS. 2A-2C) secures filter assembly 30 within enclosure 12 of electrical equipment 10. Mechanism 46 facilitates installation and removal of the filter assembly 30, 130 within enclosure 12. In one embodiment, filter assembly 30, 130 removal and replacement can be performed completely tool-less by employing mechanism 46 or other suitable mechanism. In one embodiment, mechanism 46 is a spring latch mechanism, but mechanism 46 can be embodied in other suitable types of securing mechanisms. In one embodiment, mechanism 46 temporarily secures the filter assembly 30, 130 in place when mechanism 46 is operated to engage with respective slots of enclosure 12.

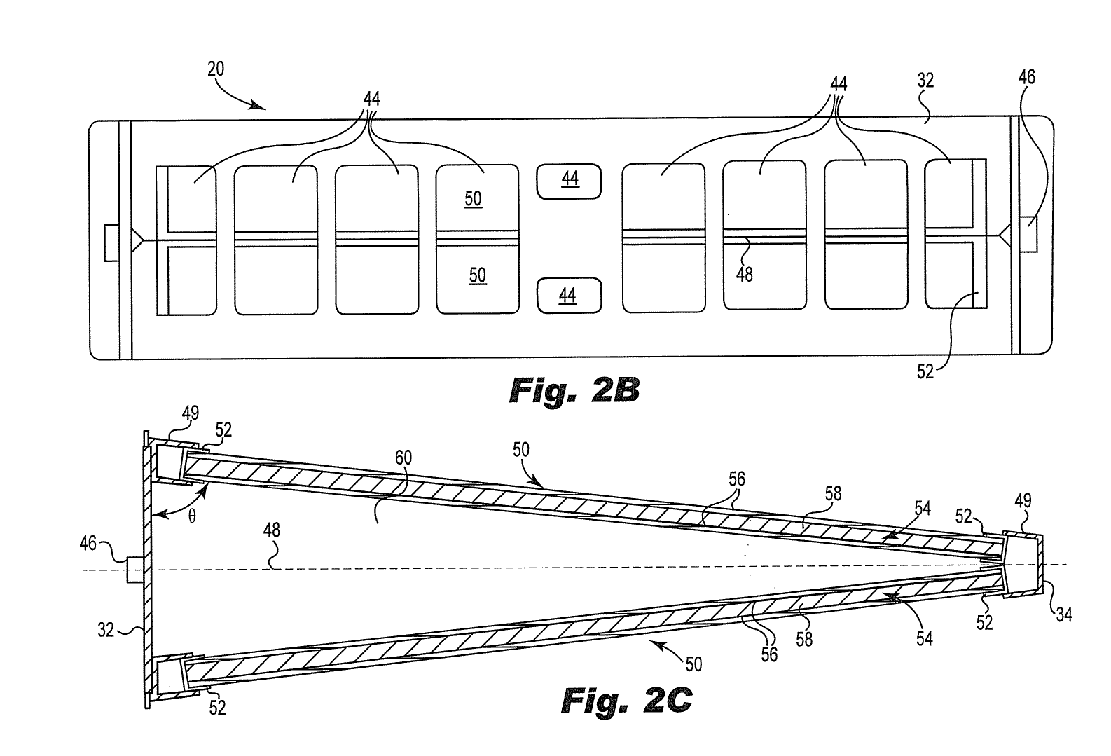

When fully assembled, filter assemblies 30, 130 are positioned within enclosure 12 so as to not protrude outside enclosure 12. This increases the usability and functionality as well as the aesthetic appeal of equipment 10. Filter assemblies 30, 130 include filter 50 (such as filter 50 illustrated in FIGS. 2A-2C and 3A-3B) which is user replaceable within filter assemblies 30, 130. In this manner, the user does not have to replace the entire filter assemblies 30, 130 but instead, only the internal filter 50. In one embodiment, filter 50 is completely self contained, trapping dust and other particulates on filter 50 within filter assembly 30, 130. This allows for easy replacement of filter 50 and particulate cleanup.

In one embodiment, filter assemblies 30, 130 are configured as tapered plenums. In one embodiment, the size and shape of filter assemblies 30, 130 depends on the geometry of electrical equipment 10 into which filter assemblies 30, 130 are installed, including the width and depth of electrical equipment 10.

FIGS. 2A-2C illustrate embodiments of primary filter assembly 30. Filter assembly 30 includes an inlet face 32, a back 34 opposing inlet face 32, a first side 36, and a second side 38 opposing first side 36. Filter assembly 30 removably retains filters 50 within the filter assembly 30. In one embodiment, inlet face 32 includes multiple inlet ports 44 spaced along inlet face 32. In one embodiment, inlet ports 44 are all the same size, although inlet ports 44 may have various sizes. The size and shape of inlet ports 44 are chosen so as to obtain the desired airflow through electrical equipment 10.

First side 36 and second side 38 are generally triangular shaped, tapering from front inlet face 32 toward back 34. Alternatively, first side 36 and second side 38 are rectangularly or otherwise shaped and include a mechanism for securing filters 50 at angle θ with respect to inlet face 32. In one embodiment, filter assemblies 30, 130 create a pressure front which makes the airflow turn as interior channel 60 gets narrower and pressure builds, forcing the air to redirect. Angle θ should be sufficient to let airflow into the inner wedge shaped channel area 60. In one embodiment, angle θ permits the airflow to turn approximately ninety degrees as it passes through filter 50 with respect to inlet face 32. In one embodiment, filter 50 is configured to balance the initial impact, and therefore airflow blockage, over the long term useable life of filter 50.

With reference to FIG. 2C, filters 50 are positioned on either side of a centerline 48, tapering from front inlet face 32 toward back 34. When assembled, filter 50 forms a first surface 40 of filter assembly 30 which follows the taper of first side 36 and second side 38. In one embodiment, filter 50 forms a second surface 42 which follows the taper of first side 36 and second side 38 opposite the centerline 48 of first surface 40. In one embodiment, filters 50 extend to perimeter edges 49 of filter assembly 30.

FIGS. 3A and 3B illustrate one embodiment of secondary filter assembly 130. Similar to primary filter assembly 30, secondary filter assembly 130 includes an inlet face 132 having inlet ports 144 and an opposing back 134. Filter assembly 130 is configured to removably retain filter 50. In one embodiment, secondary filter assembly 130 is configured to removably retain only one filter 50. In one embodiment, sides 136, 138 are tapered from inlet face 132 toward back 134 in a generally triangular manner. One embodiment of filter 50, is angled with respect to inlet face 132 at a non-right angle when assembled within filter assembly 130. Mechanism 46 engages secondary filter assembly 130 within enclosure 12 and filter assembly guides 28.

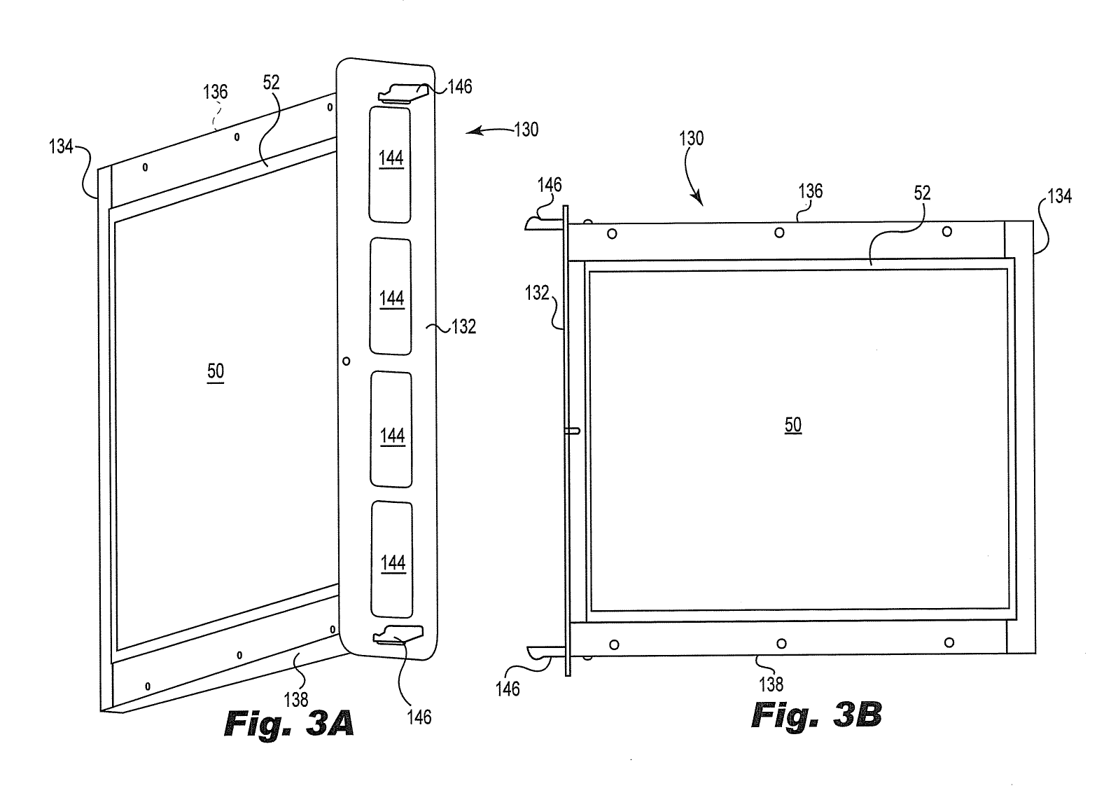

FIG. 4 illustrates one embodiment of filter 50. Filter 50 is also used to prevent dust and dirt from entering electrical equipment 10. Filter 50 can be used to cover ventilation openings in electrical equipment 10 to shield electrical components from EMI and RFI while still providing adequate airflow to cool electrical equipment 10. In one embodiment, filter 50 is rectangular although other embodiments of filter 50 have other suitably shapes. In one embodiment, filter 50 has a predetermined and substantially consistent thickness. The thickness of filter 50 is generally determined by the electrical equipment 10 and the environment in which filter 50 is employed. The length and width of filter 50 varies as suitable to assemble within the respective filter assemblies 30, 130.

Filters 50 include frame 52 disposed along the perimeter of media 54. In one embodiment, frame 52 is c-shaped with the top and bottom portions extending over the media 54. In one embodiment, frame 52 is configured around media 54 in a manner that minimizes the size of frame 52 while still allowing frame 52 to contain media 54. Media 54 may be attached within frame 52 by any suitable mechanism including friction fit, for example. Generally, frame 54 includes a fastener such as a mechanical fastener, for example, a screw, a rivet or other suitable fastener. Frame 52 provides rigidity and provides a structure for attaching filter 50 within filter assemblies 30, 130. For example, frame 52 can include mounting holes along the perimeter to secure filter 50.

In one embodiment, frame 52 is electrically conducting, thereby providing electrical bonding between media 54 and enclosure 12. In one embodiment, frame 52, which encompasses a perimeter of filter media 54, is a metallic material such as aluminum, although other materials may also be used. In one embodiment, frame 52 is formed of 2 mm thick aluminum, for example. In one embodiment, frame 52 and/or media 54 provide EMI shielding and/or RFI containment. Filter media 54 removes dust and other particulates from air drawn through filter media 54. Filter 50 includes filter media 54 including at least one inner layer 58 and opposing outer layers 56 disposed exterior to inner layers 58. Media 54 is configured as a porous media. In one embodiment, filter media 54 provides RFI containment and/or EMI shielding through a generally electrically conductive coarse substrate. In one embodiment, filter media 54 includes an expanded aluminum layered media.

Filter media 54 is configured of material suitable to trap long fiberous material and allow fine particles to pass through. Filter media 54 material is selected based on several different criteria such as the mesh variety offered, gage of the material (i.e., thickness), layer count, and opening size of the filter assembly within which the filter fits, for example. In one embodiment, inner layers 58 are a thinner gage metallic material than outer layers 56. Outer layers 56 assist with retaining inner layers 58 and provide filter media 54 a level of rigidity. In one embodiment, a thinner gage of at least one inner layer 58 is used to improve air flow and minimize air flow impedance. In one embodiment, either one of or both outer layers 56, and at least one inner layer 58, include a metallic material such as aluminum. Other suitable materials may also be used. Outer layers 56 and inner layers 58 may be made from commercially available material.

Embodiments of media 54 were tested by exposing media 54 to a mixture of airborne fiber and fine particulate matter. A reliability design verification dust chamber replicating one embodiment of field failure mechanism of electrical equipment was created. Initial thermal penalty, dust build up in key areas of the chassis, and “filter fill” thermal penalty were closely monitored throughout the test. A 3/32 inch layered aluminum material embodiment was used and tested. Other material embodiments, such as a honeycomb front panel, polyester fabric media, electrostatic media, metal mesh screen, ⅜ inch layered aluminum, quadrofoam horizontally placed, and quadrafoam diagonally placed, were used and tested. The 3/32 inch layered aluminum embodiment performed significantly better than the other tested material embodiments in testing of both initial impact and “filter fill” thermal impact. With a filter change, the selected media 54 will restore initial thermal performance, while the unfiltered equipment will continue to degrade.

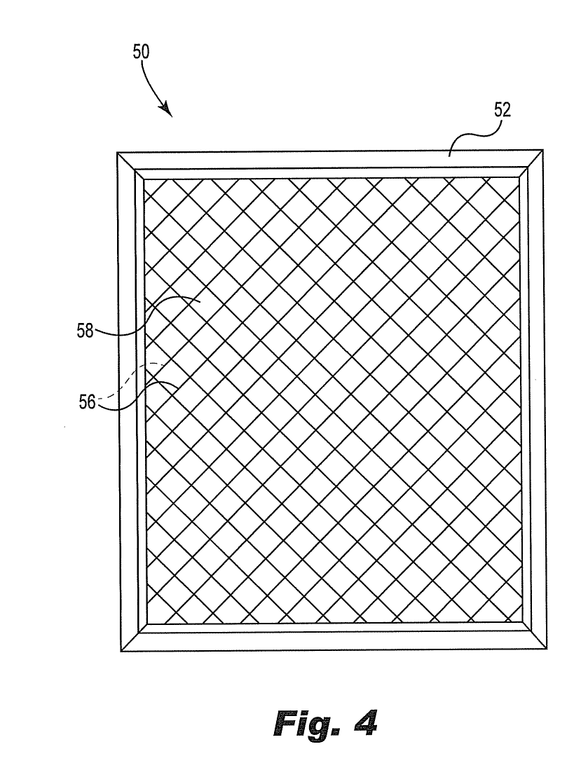

FIG. 5 illustrates one embodiment of a method of air filtration. At 92 air is circulated through the inlet of the filter assembly 30, 130. At 94, the air is redirected and smoothed through filter media 50. As the air passes through the filter media, the air is filtered at 96. The filtered air passes over electrical components at 98. In one embodiment, the air flows linearly across card cage 80 as indicated by airflow direction arrows 70, 72 in FIGS. 6A and 6B. At 100, heat is dissipated with the air flow. At 102, heat is expelled out of electrical equipment 10.

In FIGS. 6A and 6B, arrows 70 and 72 indicate a flow path of air through electrical equipment 10. Heat generated by the electrical components is dissipated by the air which flows across the electrical components in order to cool the components.

With particular regard to FIG. 6A, airflow 70 enters inlet face 32 of primary filter assembly 30. Primary filter assembly 30 is positioned between interface module card cages 80. Within filter assemblies 30, 130, filter 50 is angled at a non-right angle with respect to inlet face 32, 132 in order to smooth out airflow across electronic components and create a maximum filtration surface area for a minimal air blockage, in some cases improving airflow.

As air exits filter assembly 30 through filter media filter 50 on first surface 40 and/or second surface 42 of filter assembly 30, airflow 70 is reoriented and redirected by the angled filters 50 within filter assembly 30. In one embodiment, airflow 70 is directed both upward and downward toward interface module card cage 80. Airflow 70 is directed between electrical components within interface module card cage 80. In one embodiment, the electrical components are installed in a parallel manner running from the top to the bottom of the interface module card cage 80, thereby allowing airflow 70 to flow between the electrical components. After exiting interface module card cage 80, airflow 70 is redirected to exhaust out back 25 of electrical equipment 10. Alternatively, airflow 70 can continue out any exterior surface of enclosure 12 which enables airflow 70 to be exhausted. In one embodiment, airflow 70 exits through exhaust 82. In one embodiment, a fan 84 assists airflow 70 out of electrical equipment 10. Fan 84 can be used to drive air out of exhaust 82 or pull air through electrical equipment 10 thereby generating a continuous flow of air through electrical equipment 10 as indicated by airflow 70.

With particular reference to FIG. 6B, airflow 72 enters inlet face 132 of secondary filter assemblies 130. Secondary filter assemblies 130 are positioned along opposing sides 18, respectively, within enclosure 12. Secondary filter assembly 130 occupies a space between the interface module card cage 80 and side 18 of enclosure 12. In one embodiment, airflow 72 bypasses lower interface module card cage 80 toward exterior side walls 18, then continues up into a fabric module card cage 86 from generally vertical sides. In one embodiment, airflow 72 passes through the angled filter 50 within chassis 16 and continues into fabric module card cage 86 and is exhausted by fans 87 on each fabric module.

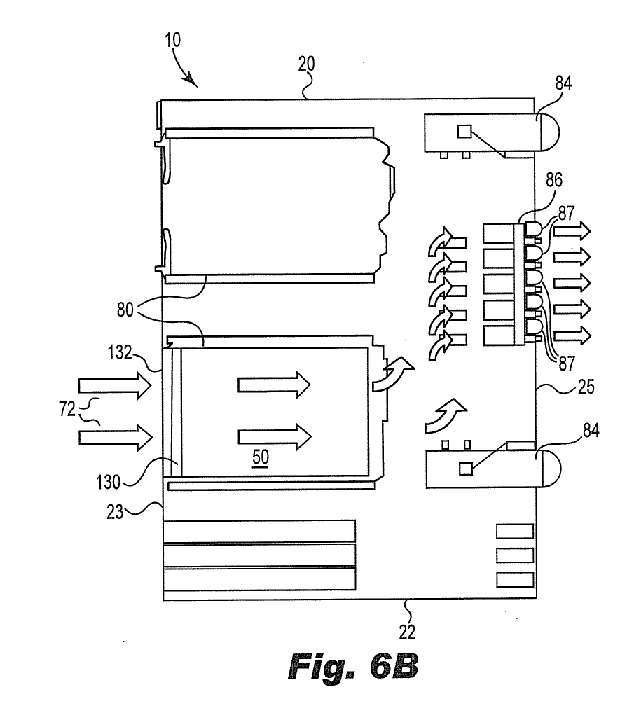

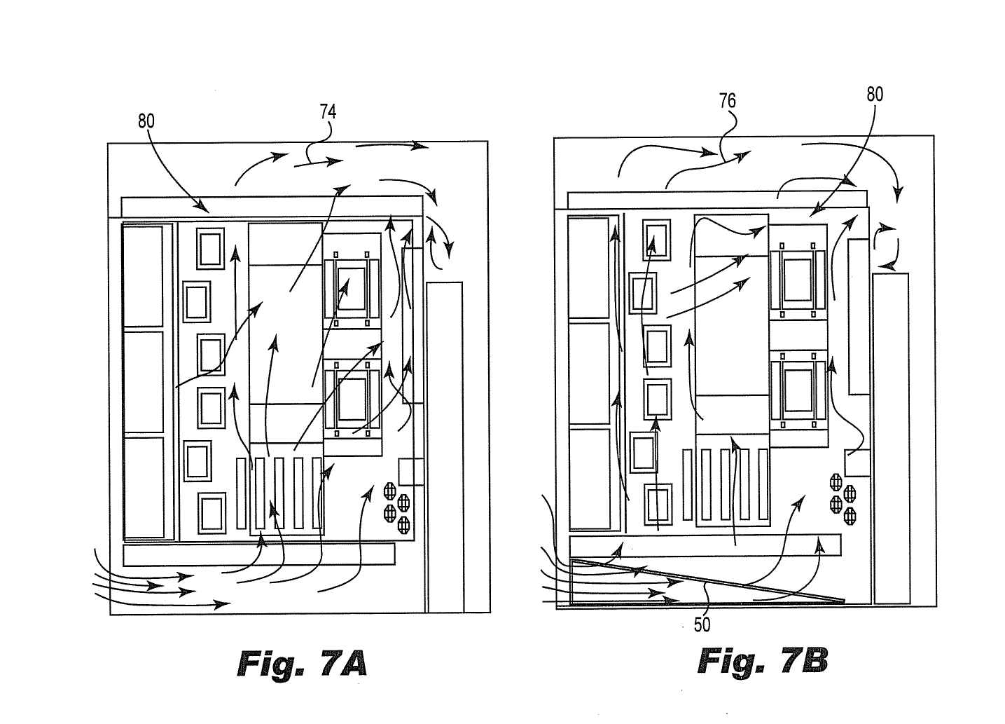

FIGS. 7A and 7B illustrate embodiments of upper interface module card cage 80 and a thermal flow 74, 76 through interface module card cage 80. In particular, FIG. 7A illustrates thermal flow 74 through interface module card cage 80 without a filter 50 installed. As illustrated in FIG. 7A, thermal flow 74 is unevenly distributed across the electrical components and interior of interface module card cage 80 when there is no filter included toward the front of the card cage 80. In one embodiment, an excess of thermal flow 74 occurs in areas which provide little or no benefit to the heated components.

With reference to FIG. 7B, thermal flow 76 is illustrated with filter assemblies 30, 130 installed and a more evenly distributed thermal flow 76 occurs throughout card cage 80. This more evenly distributed thermal flow 76 can facilitate providing beneficial cooling to the electrical components housed within interface module card cage 80. Embodiments of filter assemblies 30, 130 desirably minimize initial thermal penalties, minimize “filter full” thermal penalties, minimize particulate accumulation in the system, minimize fan speed changes, and field replaceable (i.e., zero down time), and contain dust during filter changes. In one embodiment “long fiber” particulate is contained while smaller material passes through the media 54. This reduces thermal impact of filter 50 by allowing air to flow more freely.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An air filter for electrical equipment, the air filter comprising:
metallic filter media including a first outer layer, an opposing second outer layer, and at least one inner layer disposed between the first outer layer and the opposing second outer layer; and
a frame disposed along a perimeter edge of the filter media configured to retain the filter media.

2. The air filter of claim 1, wherein the metallic material is aluminum.

3. The air filter of claim 1, wherein the at least one inner layer includes a thinner gage metallic material than the first outer layer and the opposing second outer layer.

4. The air filter of claim 1, wherein the frame comprises a metallic material.

5. The air filter of claim 1, further comprising a filter assembly configured to removably secure the frame, wherein the filter media is assembled at a non-right angle to an inlet face of the filter assembly.

6. The air filter of claim 1, wherein the filter media is configured to trap long fibrous material and allow fine particles to pass through.

7. A networking device, comprising:
an enclosure;
electrical components; and
at least one filtration assembly removably disposed within the enclosure, each of the at least one filtration assembly includes:
an inlet face;
a back opposite the inlet face;
a first side extending from a first edge of the inlet face toward the back at a non-right angle oriented toward a centerline;
a second side extending from a second edge opposite the first edge of the inlet face toward the back toward the back at a non-right angle oriented toward a centerline; and
a filter removably disposed along the first side or the second side.

8. The networking device of claim 7, wherein the at least one filtration assembly includes a primary filter assembly removably disposed within the enclosure along a first plane, and opposing secondary filter assemblies removably disposed within the enclosure along a second plane and a third plane.

9. The networking device of claim 8, wherein the secondary filter assemblies is arranged perpendicular to the primary filter assembly.

10. The networking device of claim 7, wherein the at least one filtration assembly is configured to direct airflow through the inlet face, through the filter, and into at least one chassis across the networking equipment.

11. The networking device of claim 7, wherein the at least one filtration assembly provides RFI containment to the networking apparatus.

12. The networking device of claim 7, wherein the networking equipment comprises networking cards in a parallel series within at least one chassis.

13. The networking device of claim 7, wherein the primary filter assembly includes two filters, each of the filters extending along one of the first or second sides.

14. The networking device of claim 7, wherein the filter includes media comprising a first outer layer, an opposing second outer layer, and at least one inner layer disposed between the first outer layer and the opposing second outer layer, the at least one inner layer comprised of a thinner gage metallic material than the metallic material of the first outer layer and the opposing second outer layer.

15. A filtration method in electrical equipment comprising:
providing at least one filter assembly insertably removable within a body of the electrical equipment;
circulating air to flow through an inlet of the at least one filter assembly arranged at an exterior face of the body and over a filter media of the at least one filter assembly;
redirecting and smoothing the air flow through the filter media via a tapered plenum formed within the at least one filter assembly;
filtering air as it passes through the filter media;
passing filtered air over internal electrical components housed within a chassis of the electrical equipment;
dissipating heat radiating from the electrical components as the air flows across the electrical components; and
expelling heated air out of the body of the electrical equipment.

16. The filtration method of claim 15, wherein the at least one filter assembly includes a first filter assembly arranged within the enclosure, the first filter assembly including two filter media sections, wherein a first edge of each of the two filter media sections arranged on opposing sides of the inlet and tapering toward one another while extending away from the inlet and into the enclosure to form the tapered plenum.

17. The filtration method of claim 15, wherein the at least one filter assembly further includes at least two side filter assemblies, wherein each of the side filter assemblies is arranged along an opposing side within the enclosure, wherein each of the side filter assemblies includes a single filter media section extending from a first edge arranged along a length on a first side of the inlet face to an opposing second edge oriented toward an opposing second side of the inlet.

18. The filtration method of claim 15, further comprising providing at least one fan within the electrical equipment to aid in circulating the air.

19. The filtration method of claim 15, wherein the internal electrical components are network cards arranged parallel to one another and the air flows linearly across faces of the network cards.

20. The filtration method of claim 15, further comprising removing and replacing the filter media from at least filter assembly through the use of spring latch mechanisms.
